(19) United States
(12) Patent Application Publication
(10) Pub. No.: US 2024/0367928 A1
(43) Pub. Date: Nov. 7, 2024

(54) ALIGNMENT DEVICE FOR NON-CONTACT TRANSPORT AND ALIGNMENT METHOD FOR NON-CONTACT TRANSPORT

(71) Applicant: Samsung Display Co., LTD., Yongin-si (KR)

(72) Inventors: Sungwoo RYU, Asan-si (KR); Deokho KIM, Asan-si (KR); Haeyoup KIM, Seoul (KR); Junmo PARK, Seoul (KR); Hungyu LEE, Seoul (KR)

(21) Appl. No.: 18/648,957

(22) Filed: Apr. 29, 2024

(30) Foreign Application Priority Data
May 2, 2023 (KR) 10-2023-0056847

(51) Int. Cl. B65G 67/04; B65G 67/24; G05D 3/20

(52) U.S. Cl. CPC B65G 67/04; B65G 67/24; G05D 3/20; B65G 2203/0283; B65G 2203/041

(57) ABSTRACT

An alignment device for non-contact transport includes a transport alignment movement portion which adjusts an exit position of a first product transport device, where the first product transport device linearly moves a product, which is a transport object and mounted therein, a transport position sensing portion which senses an entrance position of a second product transport device positioned to be apart from the first product transport device, where the second product transport device linearly moves the product by receiving the product linearly moved by the first product transport device, and an alignment control portion which adjusts, by controlling an operation of the transport alignment movement portion, the exit position of the first product transport device based on the entrance position of the second product transport device sensed by the transport position sensing portion.

This application claims priority to Korean Patent Application No. 10-2023-0056847, filed on May 2, 2023, and all the benefits accruing therefrom under 35 U.S.C. § 119, the content of which in its entirety is herein incorporated by reference.

### BACKGROUND

### 1. Field

One or more embodiments relate to an alignment device for non-contact transport and an alignment method for non-contact transport using the alignment device for non-contact transport, and more particularly, to an alignment device for non-contact transport, which is configured to align two non-contact transport devices, when transporting a product that is in a standing state by using a non-contact transport device such as a magnetic levitation transport device, and an alignment method for non-contact transport using the alignment device for non-contact transport.

### 2. Description of the Related Art

Generally, a deposition mask used to deposit a thin-film of a display apparatus is typically loaded on a carrier and then transported to a deposition chamber.

In addition, the deposition mask may be transported from a stoker in a standing state, rather than in a horizontal state, for the sake of transport efficiency and the minimization of a process execution space.

In general, the deposition mask is transported from the stoker to a carrier transport device by moving through a conveyor, and then, is inserted into the deposition chamber by the carrier transport device.

That is, the carrier on which the deposition mask is loaded may be inserted into the deposition chamber by the carrier transport device.

### SUMMARY

In a conventional magnetic levitation system, it may be difficult to precisely align a position of a first magnetic levitation transport portion for transporting a product with a position of a second magnetic levitation transport portion that receives a product from the first magnetic levitation transport portion, and thus, the transport efficiency may be decreased.

In other words, according to a transport device configured to transport a product in a non-contact way, such as a magnetic levitation system, a product may be transported by being floated between two non-contact transport devices that are apart from each other. Thus, it may be difficult and time-consuming to linearly align the two non-contact transport devices.

One or more embodiments include an alignment device for non-contact transport, which is capable of rapidly and precisely aligning transport positions of a first product transport portion and a second product transport portion that linearly transport a product in a non-contact way and an alignment method for non-contact transport using the alignment device for non-contact transport.

Additional aspects will be set forth in part in the description which follows and, in part, will be apparent from the description, or may be learned by practice of the embodiments of the disclosure.

According to one or more embodiments, an alignment device for non-contact transport includes a transport alignment movement portion which adjusts an exit position of a first product transport device, where the first product transport device linearly moves a product which is a transport object, a transport position sensing portion which senses an entrance position of a second product transport device positioned to be apart from the first product transport device, where the second product transport device linearly moves the product by receiving the product linearly moved by the first product transport device, and an alignment control portion which adjusts, by controlling an operation of the transport alignment movement portion, the exit position of the first product transport device based on the entrance position of the second product transport device sensed by the transport position sensing portion.

In an embodiment, the transport position sensing portion may include a first entrance position sensing portion which senses the entrance position of the second product transport device in a second direction, where a transport direction of the product transported by the first product transport device is a first direction perpendicular to the second direction in a plan view, and the transport alignment movement portion may include an alignment movement device which adjusts the exit position of the first product transport device by moving the first product transport device in a direction different from the first direction in the plan view.

In an embodiment, the transport position sensing portion may further include a linear movement direction sensing portion which senses an angle of the first product transport device with respect to a transport direction of the first product transport device in the plan view, and the transport alignment movement portion may further include a base support portion, on which the first product transport device is positioned and an angle-adjusting planar movement portion positioned below the base support portion, where the angle-adjusting planar movement portion adjusts the angle of the first product transport device with respect to the transport direction of the first product transport device by adjusting an angle of the base support portion in the plan view.

In an embodiment, the linear movement direction sensing portion may include a first distance sensing portion and a second distance sensing portion which are positioned at opposing sides of the first product transport device, respectively, to be apart from each other, where the first distance sensing portion and the second distance sensing portion sense a distance between the first product transport device and the second product transport device.

In an embodiment, the angle-adjusting planar movement portion may include a plurality of 2-axis movement units movable in the first direction and the second direction.

In an embodiment, the transport position sensing portion may further include a second entrance position sensing portion which senses a height of the first product transport device, and the transport alignment movement portion may further include a transport ascend and descend device which ascends and descends the first product transport device.

In an embodiment, the first entrance position sensing portion and the second entrance position sensing portion may include a sensing portion which is mounted at one of a first transport portion including the first product transport device and a second transport portion including the second product transport device, and a reference position display portion mounted at the other of the first transport portion and the second transport portion, where the reference position display portion displays a reference position identified through an image captured by the sensing portion.

In an embodiment, the alignment device may further include a transport driving portion which moves the first product transport device toward the second product transport device and sets a distance between the first product transport device and the second product transport device, where the transport alignment movement portion may include a distance-adjusting device which re-adjusts the distance between the first product transport device and the second product transport device, which is set by the transport driving portion, by forwardly or backwardly moving the first product transport device in a direction identical to a transport direction of the product.

According to one or more embodiments, an alignment method for non-contact transport for aligning an exit of a first product transport device with an entrance of a second product transport device when linearly moving a product from the first product transport device to the second product transport device, which are positioned to be apart from each other, wherein each of the first product transport device and the second product transport device linearly moves the product, the alignment method for non-contact transport comprises, performing a position sensing operation by identifying a position of the second product transport device and performing a transport position aligning operation by linearly aligning the first product transport device with the second product transport device by adjusting a position of the first product transport device after the performing the position sensing operation.

In an embodiment, wherein the performing the position sensing operation may include performing a first position sensing process by sensing a position of the second product transport device with respect to a second direction, where a linear movement direction of the product is a first direction different from the second direction, and performing a second position sensing process by sensing a position of the second product transport device with respect to a third direction different from the first direction, and the performing the transport position aligning operation may include performing a process of moving the first product transport device in the second direction or the third direction.

In an embodiment, the performing the first position sensing process and the performing the second position sensing process may include sensing the positions of the second product transport device with respect to the second direction and the third direction by identifying a position-display hole of a target bracket positioned at the second product transport device through a sensing portion based on a camera, which is positioned at the first product transport device.

In an embodiment, the performing the position sensing operation may further include performing a transport direction sensing process by sensing an angle of the first product transport device with respect to a transport direction of the first product transport device in a plan view, and the performing the transport position aligning operation may further include performing a transport direction changing process by changing the angle of the first product transport device with respect to the transport direction of the first product transport device in the plan view, where the performing the transport direction changing process may include changing the angle of the first product transport device with respect to the transport direction of the first product transport device in the plan view by selectively operating a plurality of 2-axis movement units which moves a base support portion with the first product transport device positioned thereon in the first direction and second direction.

In an embodiment, the performing the transport direction sensing process may include sensing the angle of the first product transport device in the plan view by measuring a distance between the first product transport device and the second product transport device through a first distance sensing portion and a second distance sensing portion which are positioned at both sides of the first product transport device to be apart from each other.

In an embodiment, the alignment method for non-contact transport may further include, before the performing the position sensing operation, performing a transport device movement operation by moving the first product transport device via a transport driving portion and positioning the first product transport device at a transport position apart from the second product transport device, where the performing the transport position aligning operation may further include performing a distance re-adjusting process by re-adjusting a distance between the first product transport device and the second product transport device by forwardly or backwardly moving, in a direction which is identical to a transport direction of the product, where the first product transport device is positioned at the transport position apart from the second product transport device.

### BRIEF DESCRIPTION OF THE DRAWINGS

The above and other features of certain embodiments of the disclosure will be more apparent from the following description taken in conjunction with the accompanying drawings, in which:

FIG. 1 is a side view of an alignment device for non-contact transport, according to an embodiment;

FIG. 2 is a front view of an example of a first product transport portion of an alignment device for non-contact transport according to an embodiment;

FIG. 3 is a plan view of a transport position sensing portion of an alignment device for non-contact transport according to an embodiment;

FIGS. 4 and 5 are side views of an implementation example of a transport position sensing portion of an alignment device for non-contact transport according to an embodiment; and

FIG. 6 is a flowchart of an alignment method for non-contact transport, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or element is referred to as being “on” another layer, area, or element, it can be directly or indirectly formed on the other layer, region, or element. That is, for example, intervening layers, regions, or elements may be present. In contrast, when an element is referred to as being “directly on” another element, there are no intervening elements present.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

In the embodiments hereinafter, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

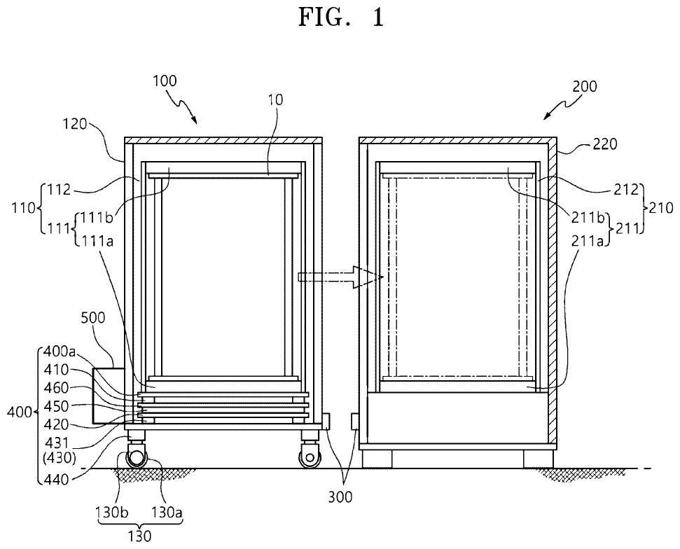

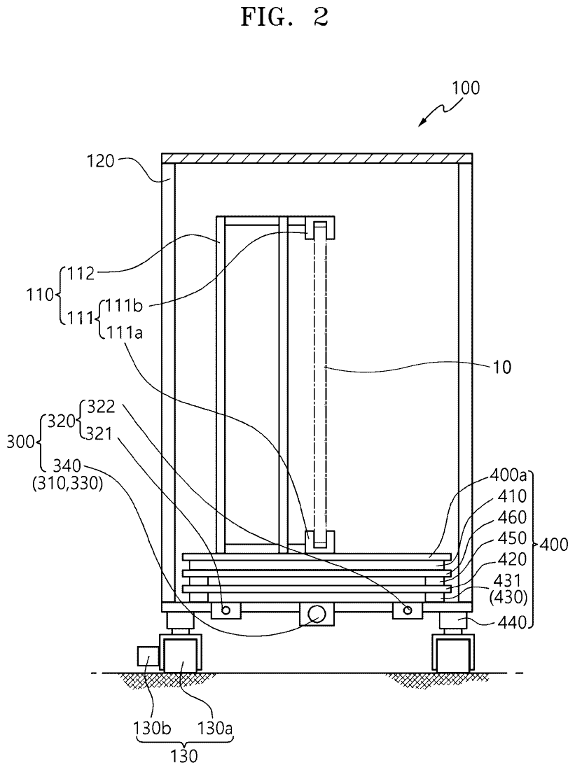

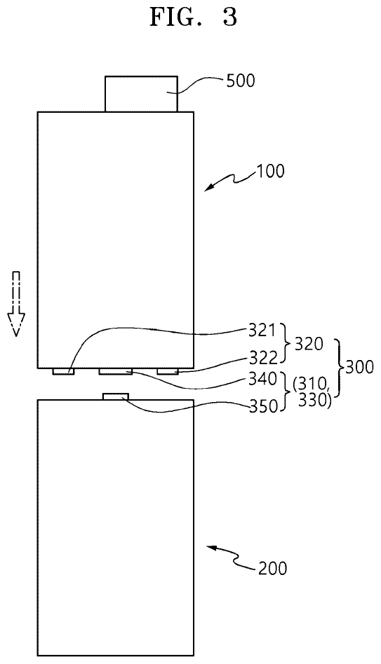

FIG. 1 is a side view of an alignment device for non-contact transport according to an embodiment, FIG. 2 is a front view of an example of a first product transport portion 100 of the alignment device for non-contact transport according to an embodiment, and FIG. 3 is a plan view of a transport position sensing portion 300 of the alignment device for non-contact transport according to an embodiment.

The alignment device for non-contact transport according to an embodiment will hereinafter be described in detail with reference to FIGS. 1 to 3.

The alignment device for non-contact transport according to an embodiment may include a first product transport portion 100 including a first product transport device 110 that linearly shifts a product 10 mounted therein. In an embodiment, for example, the alignment device for non-contact transport may transport the product 10 that is mounted, while maintaining the product 10 in a state vertical to the ground surface.

The first product transport portion 100 may include a first product-containing housing portion 120 in which the first product transport device 110 is positioned.

The first product transport portion 100 may include the first product transport device 110, in which the product 10 (i.e., an object of transport) is mounted in a standing state, where the first product transport device 110 is capable of linearly moving the product 10, and the first product-containing housing portion 120 in which the first product transport device 110 is mounted.

In an embodiment, for example, the first product-containing housing portion 120 may include a first opening and closing portion at a front surface thereof toward a second product-transport housing portion to be described below and a second opening and closing portion at a rear surface thereof, where the first opening and closing portion is capable of being opened or closed to withdraw the product 10 contained in the first product-containing housing portion 120, and the second opening and closing portion is capable of being opened or closed to introduce the product 10 into the first product-containing housing portion 120.

The first opening and closing portion and the second opening and closing portion may positioned opposite to each other in a direction in which the product 10 is linearly moved by the first product transport device 110, and thus, as the second opening and closing portion is opened, the product 10 may be introduced into the first product-containing housing portion 120 and may be loaded on the first product transport device 110 in a standing state, and as the first opening and closing portion is opened, the product 10 loaded on the first product transport device 110 may be withdrawn to the outside through an operation of the first product transport device 110.

The first product transport portion 100 may receive the product 10 through a transport device capable of picking up and introducing the product 10 while the second opening and closing portion is being opened, such as a transport robot or a fork portion, and the product 10 may be loaded on the first product transport device 110.

In an embodiment, while the first opening and closing portion is being opened, the first product transport portion 100 may linearly move the product 10 to a second product transport portion 200 through an operation of the first product transport device 110.

In an embodiment, the first product transport portion 100 may further include a transport driving portion 130 configured to move the first product transport device 110 toward a second product transport device 210, the transport driving portion 130 may move the first product transport device 110 toward the second product transport portion 200 after the product 10 is loaded on the first product transport device 110 and may position the first product transport device 110 to be apart by a predetermined distance from the second product transport device 210 of the second product transport portion 200.

In an embodiment, for example, the transport driving portion 130 may include a plurality of driving wheel portions 130a rollable on the ground and a driving motor portion 130b configured to rotate at least one of the plurality of driving wheel portions 130a.

In an embodiment, for example, the transport driving portion 130 may move the first product-containing housing portion 120 toward the second product transport portion 200 through the plurality of driving wheel portions 130a mounted on a lower surface of the first product-containing housing portion 120 and rotated by a motor and thus may position the first product transport device 110 to be apart by a predetermined distance from the second product transport device 210.

In an embodiment, although not shown, the transport driving portion 130 may include a movement panel portion (not shown) positioned to be capable of being withdrawn, through the first opening and closing portion, from the first product-containing housing portion 120 and a movement wheel portion (not shown) provided below the movement panel portion (not shown) and rollable on the ground and rotated by a motor to move the movement panel portion (not shown) to the outside of the first product-containing housing portion 120.

Although not shown, the transport driving portion 130 may have a moving wheel car structure including the plurality of driving wheel portions 130a, above which the first product transport portion 100 is positioned and which is rotated by a motor, or may be implemented by being variously changed by using a well-known or conventional driving structure capable of moving the first product transport device 110 to a predetermined transport position that is apart from the second product transport device 210. Thus, further detailed descriptions thereof will be omitted.

In such an embodiment, the transport driving portion 130 may have a wheel car structure configured to directly move the first product-containing housing portion 120 to a second product-containing housing portion 220 through the driving wheel portions 130a or may have a structure in which the first product-containing housing portion 120 is fixed at a certain position and a movement panel portion (not shown) positioned in the first product-containing housing portion 120 is moved toward the second product-containing housing portion 220, where the first product transport device 110 may be moved near to the second product transport device 210 through the well-known driving or the well-known movement structure, for example.

The second product transport portion 200 may receive, by using the second product transport device 210, the product linearly moved by the first product transport device 110 and may linearly transport the product to a predetermined position.

In an embodiment, for example, the second product transport portion 200 may include the second product transport device 210 configured to receive the product linearly moved by the first product transport device 110 and linearly move the product and the second product-containing housing portion 220 in which the second product transport device 210 is positioned. In such an embodiment, for example, the second product portion 200 may complete the transport operation of the product 10 by transporting the product 10 to a predetermined position, that is, into the second product-containing housing portion 220, by using the second product transport device 210.

In an embodiment, for example, the second product-containing housing portion 220 may include a third opening and closing portion capable of being opened or closed at a surface thereof facing the first product transport portion 100, where the product 10 may be introduced into the second product-containing housing portion 220 as the third opening and closing portion is opened, and after the product 10 is inserted into the second product-containing housing portion 220, the second product-containing housing portion 220 may be closed as the third opening and closing portion is closed.

Each of the first opening and closing portion, the second opening and closing portion, and the third opening and closing portion may have a slide opening and closing structure, for example. In addition, each of the first to third opening and closing portions may be implemented by being variously changed by using well-known or conventional opening and closing structures. Thus, further detailed descriptions thereof will be omitted.

In an embodiment, for example, the product 10 may be a carrier on which a deposition mask is placed, and for example, the second product transport portion 200 may be a deposition chamber portion into which the carrier on which the deposition mask is placed is inserted and in which a deposition process is performed.

In an embodiment, for example, the first product transport portion 100 may be a deposition mask-carrier transport portion configured to guide, through the first product transport device 110, the carrier on which the deposition mask is mounted, to the second product transport portion 200.

It would be understood that other well-known transport structures may be used. In an embodiment, for example, the first product transport portion 100 and the second product transport portion 200 may linearly move the product 10, which is a transport object, by using the first product transport device 110 and the second product transport device 210 that are apart from each other, thereby transmitting the product 10 from the first product transport device 110 to the second product transport device 210.

In an embodiment, for example, the first product transport device 110 and the second product transport device 210 may be magnetic levitation movement devices configured to linearly move, through magnetic levitation, the product 10, which is loaded in a standing state.

In an embodiment, for example, the first product transport device 110 may include a first magnetic levitation movement device 111 configured to linearly move, through magnetic levitation, the product 10 mounted in a standing state, and a first support frame portion 112 configured to support a position of the first magnetic levitation movement device 111.

The first magnetic levitation movement device 111 may include a first magnetic levitation lower movement portion 111a including a first lower rail portion into which a portion of a lower end of the product 10 is inserted and a first magnetic levitation upper movement portion 111b including a first upper rail portion into which a portion of an upper end of the product 10 is inserted.

The first magnetic levitation movement device 111 may mount the product 10 between the first lower rail portion and the first upper rail portion and may float, through magnetic power, a carrier, that is, the product 10, between the first lower rail portion and the first upper rail portion and may linearly move the product 10.

In an embodiment, for example, the second product transport device 210 may include a second magnetic levitation movement device 211 configured to linearly move, through magnetic levitation, the product 10 mounted in a standing state, and a second support frame portion 212 configured to support a position of the second magnetic levitation movement device 211.

The second magnetic levitation movement device 211 may include a second magnetic levitation lower movement portion 211a including a second lower rail portion into which a portion of a lower end of the product 10 is inserted and a second magnetic levitation upper movement portion 211b including a second upper rail portion into which a portion of an upper end of the product 10 is inserted.

The second magnetic levitation movement device 211 may mount the product 10 between the second lower rail portion and the second upper rail portion and may float, through magnetic power, a carrier, that is, the product 10, between the second lower rail portion and the second upper rail portion and may linearly move the product 10 and halt the product 10 at a predetermined position.

In an embodiment, for example, the first magnetic levitation movement device 111 and the second magnetic levitation movement device 211 may be the magnetic levitation devices having a same structure as each other. The product 10 positioned between the first lower rail portion and the first upper rail portion may be inserted between the second lower rail portion and the second upper rail portion, and the product 10 may be linearly moved between the second lower rail portion and the second upper rail portion and halted at a predetermined position.

In an embodiment, for example, the first product transport device 110 and the second product transport device 210 may have a same structure as each other and may thus stably transmit the product 10 in a linear direction.

The first product transport device 110 and the second product transport device 210 may be transport devices including rails into which the product 10 is inserted and loaded, the rails including a plurality of transport wheels, or may be implemented by being variously changed by using a well-known rail movement structure configured to linearly move the product 10 along a rail on which the product 10 is mounted to be movable. In addition, the first product transport device 110 and the second product transport device 210 may be implemented by being variously changed by using a well-known movement structure configured to move the product 10 between two mounting structures on which the product 10 is mounted.

The alignment device for non-contact transport according to an embodiment may include: a transport position sensing portion 300 that senses an entrance position of the second product transport device 210; a transport alignment movement portion 400 that adjusts an exit position of the first product transport device 110 based on the entrance position of the second product transport device 210 positioned by the transport position sensing portion 300; and an alignment control portion 500 that aligns, by controlling an operation of the transport alignment movement portion 400, the exit position of the first product transport device 110 based on the entrance position of the second product transport device 210 sensed by the transport position sensing portion 300.

The first product transport device 110 and the second product transport device 210 may be positioned to be apart from each other and not to be in contact with each other, and thus, the product 10 may be accurately transported in a linear direction, only when an exit of the first product transport device 110, through which the product 10 is discharged, and an entrance of the second product transport device 210, through which the product 10 is introduced, correspond to each other.

The alignment control portion 500 may align, by controlling the operation of the transport alignment movement portion 400, the exit position of the first product transport device 110 based on the entrance position of the second product transport device 210 sensed by the transport position sensing portion 300, and thus, the first product transport device 110 and the second product transport device 210 may be linearly aligned in a transport direction of the product 10.

The transport position sensing portion 300 may include a first entrance position sensing portion 310 configured to sense the entrance position of the second product transport device 210 in a direction different from a transport direction of the product 10 in a plan view, that is, a direction different from the directions in which the product 10 is transported by the first and second product transport devices 110 and 210.

Also, the transport alignment movement portion 400 may include an alignment movement device 410 configured to adjust the exit position of the first product transport device 110 by moving the first product transport device 110 in a direction different from the transport direction of the product 10 in a plan view, that is, a direction different from the directions in which the product 10 is transported by the first and second product transport devices 110 and 210.

In an embodiment, for example, the alignment movement device 410 may move the first product transport device 110 in a direction perpendicular to the transport direction of the product 10 in the plan view and may adjust the exit position of the first product transport device 110 to be aligned to the entrance of the second product transport device 210.

In an embodiment, for example, the transport alignment movement portion 400 may further include a first alignment movement plate portion 400a, on an upper surface of which the first product transport device 110 is mounted, and the alignment movement device 410 may move the first alignment movement plate portion 400a in a direction perpendicular to the transport direction of the product 10 in a plan view.

That is, the alignment movement device 410 may move the first product transport device 110 in a direction perpendicular to the transport direction of the product 10 in a plan view and may align the exit position of the first product transport device 110 to correspond to the entrance position of the second product transport device 210.

In an embodiment, for example, when the transport direction of the product 10 is an X-axis direction (or a first direction), the alignment movement device 410 may move the first product transport device 110 in a Y-axis direction (or a second direction), and thus, may align the first product transport device 110 and the second product transport device 210 in a way such that the exit of the first product transport device 110 and the entrance of the second product transport device 210 may correspond to each other in the Y-axis direction.

Also, the transport position sensing portion 300 may further include a linear movement direction sensing portion 320 that senses an angle of the first product transport device 110 with respect to the transport direction thereof in a plan view.

The linear movement direction sensing portion 320 may be configured to sense the angle of the first product transport device 110 in the plan view and may include a first distance sensing portion 321 and a second distance sensing portion 322 that are positioned to be apart from each other at both opposing sides of the first product transport device 110 and configured to sense a distance of the first product transport device 110 from the second product transport portion 200.

The first distance sensing portion 321 and the second distance sensing portion 322 may be positioned at a same height in the Y-axis direction perpendicular to the transport direction of the product 10 to be apart from each other and each may sense a distance between the first product transport portion 100 and the second product transport portion 200 to sense the angle of the first product transport device 110 in the plan view.

The first distance sensing portion 321 and the second distance sensing portion 322 may be mounted on a front surface of the first product transport portion 100 facing the second product transport portion 200, that is, a front surface of the first product-containing housing portion 120 facing the second product-containing housing portion 220, and each of the first and second distance sensing portions 321 and 322 may sense the distance between the first product transport portion 100 and the second product transport portion 200 in the plan view, while being apart from each other.

The first distance sensing portion 321 and the second distance sensing portion 322 may be positioned at both opposing sides of the first product transport device 110 to be apart from each other and each may sense the distance between the first product transport portion 100 and the second product transport portion 200, and when the distance sensed by the first distance sensing portion 321 and the distance sensed by the second distance sensing portion 322 are different from each other, it may be identified that the transport direction of the second product transport device 210 positioned to be fixed deviates from the first product transport device 110, and when the sensed distances are the same as each other, it may be identified that the first product transport device 110 and the second product transport device 210 are linearly arranged to correspond to the transport direction of the product 10.

Each of the first distance sensing portion 321 and the second distance sensing portion 322 may sense the distance between the first product transport portion 100 and the second product transport portion 200 to identify an angle of the first product transport device 110 with respect to the transport direction thereof in a plan view. Also, the alignment control portion 500 may control an operation of an angle-adjusting planar movement portion 430 including a plurality of 2-axis movement units 431, that is, four 2-axis movement nits 431 to be described below to linearly align the two linear transport devices, that is, the first product transport device 110 and the second product transport device 210.

In an embodiment, the transport alignment movement portion 400 may further include a base support portion 420, on an upper portion of which the first product transport device 110 is positioned, and the angle-adjusting planar movement portion 430 positioned below the base support portion 420 and adjusting an angle of the base support portion 420 in a plan view to adjust the angle of the first product transport device 110 with respect to the transport direction thereof.

The angle-adjusting planar movement portion 430 may include the plurality of 2-axis movement units 431 capable of moving in the X-axis direction and the Y-axis direction.

The 2-axis movement units 431 may be any conventional or well-known unit capable of moving the base support portion 420 in the X axis, which is the transport direction of the product 10, and the Y axis, which is a direction perpendicular to the X axis, and thus, more detailed descriptions thereof will be omitted.

In an embodiment, for example, the plurality of 2-axis movement units 431 may include a pair of 2-axis movement units at both opposing sides of a front end of the product 10 and a pair of 2-axis movement units at both opposing sides of a rear end of the product, with respect to the transport direction of the product 10, thereby including the total of four 2-axis movement units 431.

The transport alignment movement portion 400 may adjust a transport angle of the first product transport device 110 in a plan view in a way such that the first product transport device 110 and the second product transport device 210 linearly correspond to each other.

The transport alignment movement portion 400 including the plurality of 2-axis movement units 431, that is, four 2-axis movement units 431, may adjust the transport angle of the first product transport device 110 in the plan view in a way such that the first product transport device 110 and the second product transport device 210 may linearly correspond to each other. Thus, the product 10 may be stably transported through the two linear transport devices, that is, the first product transport device 110 and the second product transport device 210.

Also, the transport position sensing portion 300 may further include a second entrance position sensing portion 330 that senses a height of the first product transport device 110.

Also, the transport alignment movement portion 400 may further include a transport ascend and descend device 440 that adjusts a height of the exit of the first product transport device 110 by making the first product transport device 110 ascend and descend.

In an embodiment, for example, the transport ascend and descend device 440 may be mounted above the driving wheel portions 130a and may adjust the height of the exit of the first product transport device 110.

Also, although not shown, the transport ascend and descend device 440 may be positioned between a lower surface of a product-transport housing portion and the first product transport device 110 and may adjust the height of the first product transport device 110.

The transport ascend and descend device 440 may be positioned in a multiple number in the transport direction of the first product transport device 110 and may horizontally position the first product transport device 110 in a lengthwise direction, that is, the transport direction of the product 10.

In an embodiment, for example, the transport ascend and descend device 440 may be a linear actuator adopting a ball-screw method. However, in addition thereto, the transport ascend and descend device 440 may be implemented by being variously changed, for example, by using a well-known ascend and descend device, such as a rack and pinion structure including a hydraulic cylinder, a rack gear, and a pinion gear interlocking with the rack gear and rotated by a motor, where the rack and pinion structure is configured to convert a rotational force of the motor to linear movement. Thus, more detailed descriptions thereof will be omitted.

When the first product transport portion 100 is moved by the transport driving portion 130 toward the second product transport portion 200 and is positioned at a predetermined transport position to face the second product transport portion 200, the height of the first product transport device 110 may vary based on the state of a ground surface.

In such an embodiment, when the driving wheel portions 130a drive by rolling on the ground surface and the first product transport device 110 is moved to the predetermined position with respect to the second product transport device 210, the height of the exit of the first product transport device 110 may vary based on the state of the ground surface. Thus, the transport ascend and descend device 440 may adjust the height of the exit of the first product transport device 110 so that the height of the exit of the first product transport device 110 is the same as the height of the entrance of the second product transport device 210 provided at the transport position of the product and having the same structure as the first product transport device 110.

The first entrance position sensing portion 310 and the second entrance position sensing portion 330 may include a sensing portion 340 based on a camera which is mounted at one side of the first product transport portion 100 and the second product transport portion 200 and a reference position display portion 350 mounted at another side of the first product transport portion 100 and the second product transport portion 200 to display a reference position identified by the sensing portion 340 through an image.

In an embodiment, for example, the sensing portion 340 may be a camera-based Indoor Positioning system (IPS) sensor, and in addition thereto, well-known camera-based position sensors may be used.

In an embodiment, for example, the reference position display portion 350 may be a target bracket in which a position-display hole 351 for displaying the reference position is provided.

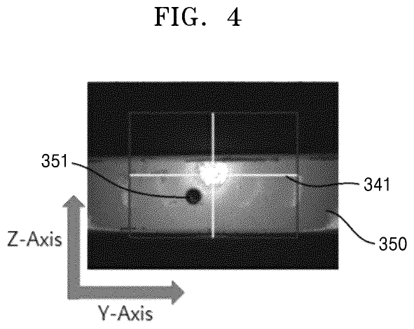

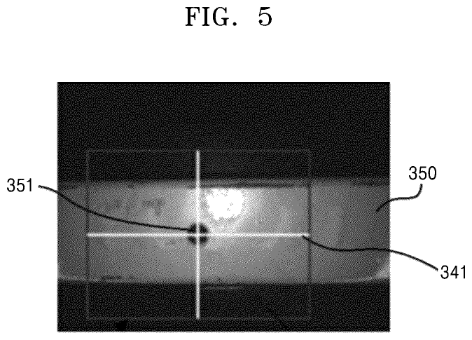

FIGS. 4 and 5 are side views of an example of the transport position sensing portion 300 in an alignment device for non-contact transport according to an embodiment and shows an example in which the reference position display portion 350 is photographed by the sensing portion 340, which is an IPS sensor, and positions in a Y axis direction and a Z-axis direction (or a third direction) are sensed.

FIG. 4 illustrates an example in which, before the alignment, that is, before the position of the first product transport device 110 is aligned by the transport alignment movement portion 400, the reference position display portion 350 is photographed by the sensing portion 340, which is a camera-based IPS sensor. FIG. 5 illustrates an example in which, after the alignment, the first product transport device 110 is moved by the transport alignment movement portion 400 and is aligned with the second product transport device 210.

Referring to FIG. 4, in an image captured by the sensing portion 340, a cross axis 341 for sensing the position-display hole 351 may be indicated, and with reference to the position-display hole 351 of the reference position display portion 350 positioned at an opposite side with respect to the cross axis 341, coordinate values in 2-axis directions in the cross axis 341, that is, coordinate values in a Y-axis direction and a Z-axis direction may be measured.

The sensing portion 340 may be a camera-based sensor capable of measuring position values with respect to two directions from a reference point, by sensing a hole or a reflection plate by using a camera. More detailed descriptions thereof will be omitted.

The alignment control portion 500 may receive the coordinate values in the Y-axis direction and the Z-axis direction with respect to the cross axis 341 from the sensing portion 340, as illustrated in FIG. 4, and may control an operation of the alignment movement device 410 to adjust a position of the first product transport device 110 in the Y-axis direction and may control an operation of the transport ascend and descend device 440 to adjust a position of the first product transport device 110 in the Z-axis direction, so that a cross point of the cross axis 341 may be positioned at the center of the position-display hole 351, as illustrated in FIG. 5. Thus, the positions of the first product transport device 110 and the second product transport device 210 in the Y-axis direction and the Z-axis direction may be effectively aligned.

Referring back to FIGS. 1 to 3, the transport alignment movement portion 400 may further include a distance-adjusting device 450 configured to adjust a distance between the first product transport device 110 and the second product transport device 210 by forwardly or backwardly moving the first product transport device 110 in the same direction as the transport direction of the product 10.

In an embodiment, the transport alignment movement portion 400 may further include a second alignment movement plate portion 460, on an upper surface of which the alignment movement device 410 is positioned, and which is linearly moved by the distance-adjusting device 450.

The distance-adjusting device 450 may adjust the distance between the first product transport device and the second product transport device by moving, together, forwardly or backwardly in the X-axis direction, that is, the same direction as the transport direction of the product 10, the alignment movement device 410 positioned on the base support portion 420 and mounted on the second alignment movement plate portion 460 and the first alignment movement plate portion 400a, on an upper surface of which the first product transport device 110 is mounted.

The first distance sensing portion 321 and the second distance sensing portion 322 may be mounted on the second alignment movement plate portion 460 and may move together with the second alignment movement plate portion 460 and may sense the distance of between the first product transport portion 100 and the second product transport portion 200. Also, the alignment control portion 500 may receive distance information from the first distance sensing portion 321 and the second distance sensing portion 322 that are moved forwardly or backwardly together with the second alignment movement plate portion 460, and thus, may not only align an angle of the first product transport device 110 in a plan view, but may also finely adjust a distance between an exit of the first product transport device 110 and an entrance of the first product transport device 110.

In an embodiment, the distance-adjusting device 450 may additionally move the first product transport device 110 in the transport direction of the product 10, after the transport driving portion 130 primarily moves the first product transport device 110 and the second product transport device 210 to a predetermined transport position, and thus, may relatively more finely adjust the distance between the first product transport device 110 and the second product transport device 210.

In an embodiment, for example, the alignment movement device 410 and the distance-adjusting device 450 may be linear actuators adopting a ball-screw method. However, in addition thereto, the alignment movement device 410 and the distance-adjusting device 450 may be implemented by being variously changed, for example, by using a well-known ascend and descend device, such as a rack and pinion structure including a hydraulic cylinder, a rack gear, and a pinion gear interlocking with the rack gear and rotated by a motor, where the rack and pinion structure is configured to convert a rotational force of the motor to linear movement. Thus, more detailed descriptions thereof will be omitted.

According to an embodiment of the alignment device for non-contact transport, when, in particular, the first product transport device 110 is moved by the transport driving portion 130 to be positioned to face the second product transport device 210 at a predetermined distance from the second product transport device 210, the transport position sensing portion 300 may sense the position of the second product transport device 210 and the transport alignment movement portion 400 may move the position of the first product transport device 110 in a way such that the positions of the first product transport device 110 and the second product transport device 210 may be linearly aligned.

In such an embodiment, when a transport direction of the product 10 is the X-axis direction, the first entrance position sensing portion 310 may sense the position of the first product transport device 110 in the Y-axis direction, the second entrance position sensing portion 330 may sense the position of the second product transport device 210 in the Z-axis direction, and the first distance sensing portion 321 and the second distance sensing portion 322 which are included in the linear movement direction sensing portion 320 may measure a distance between the first product transport device 110 and the second product transport device 210.

The alignment control portion may control operations of the alignment movement device 410 and the transport ascend and descend device 440 through position information of the Y-axis direction and the Z-axis direction of the first product transport device 110, where the position information is received from the first entrance position sensing portion 310 and the second entrance position sensing portion 330, to align the positions of first product transport device 110 and the second product transport device 210 in the Y-axis direction and the Z-axis direction.

In such an embodiment, the alignment control portion may identify a deviation angle of the first product transport device 110 in a transport direction of the first product transport device 110, that is, in a plan view, through the distance information received from the first distance sensing portion 321 and the second distance sensing portion 322 positioned at both opposing sides of the first product transport device 110, and may linearly align the first product transport device 110 and the second product transport device 210 in the X-axis direction by controlling an operation of the angle-adjusting planar movement portion 430.

In such an embodiment, after the first product transport device 110 and the second product transport device 210 are linearly aligned in the X-axis direction, the alignment control portion may identify again the distance between the first product transport device 110 and the second product transport device 210 through the distance information received from the first distance sensing portion 321 and the second distance sensing portion 322 and may control an operation of the distance-adjusting device 450, thereby finely re-adjusting the distance between the first product transport device 110 and the second product transport device 210.

Based on the transport direction of the product 10, which is the X-axis direction, the alignment device for non-contact transport may align the positions of the first product transport device 110 and the second product transport device 210 not only in the Y-axis direction and the Z-axis direction, but also in a plan view, to precisely linearly align the first product transport device 110 and the second product transport device 210 at distances apart from each other.

In such an embodiment, after the alignment of the first product transport device 110 and the second product transport device 210 in the axial directions is completed, the alignment device for non-contact transport may control the operation of the distance-adjusting device 450 and may finely re-adjust the distance between the first product transport device 110 and the second product transport device 210, and thus, may effectively prevent malfunction during the transport and may precisely and reliably transmit the product 10 from the first product transport device 110 to the second product transport device 210.

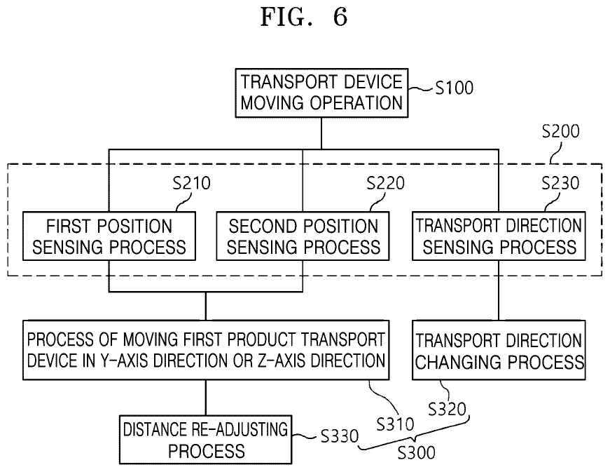

FIG. 6 is a flowchart of an alignment method for non-contact transport according to an embodiment, and the alignment method for non-contact transport according to an embodiment will hereinafter be described in detail with reference to FIGS. 1 and 6.

An embodiment of the alignment method for non-contact transport may include a transport device moving operation S100 of aligning an entrance of the first product transport device 110 and an exit of the second product transport device 210 when linearly moving the product 10 through the first product transport device 110 and the second product transport device 210, which are positioned to be apart from each other and configured to linearly move the product 10.

In such an embodiment, the alignment method for non-contact transport may include a position sensing operation S200 of identifying a position of the second product transport device 210 and, after the position sensing operation S200, a transport position aligning operation S300 of linearly aligning the first product transport device 110 and the second product transport device 210 by adjusting a position of the first product transport device 110.

The position sensing operation S200 may include a first position sensing process S210 of sensing a position of the second product transport device 210 in a Y-axis direction and a second position sensing process S220 of sensing a position of the second product transport device 210 in a Z-axis direction, when a linear movement direction of the product 10 is an X-axis direction.

Each of the first position sensing process S210 and the second position sensing process S220 may include sensing the positions of the second product transport device 210 in the Y-axis direction and the Z-axis direction by identifying the position-display hole 351 of a target bracket positioned at the second product transport device 210 through the camera-based sensing portion 340 positioned at the first product transport device 110.

In an embodiment, for example, the sensing portion 340 may be a camera-based IPS sensor, and in addition thereto, well-known camera-based position sensors may be used.

Each of the first position sensing process S210 and the second position sensing process S220 may sense the positions of the second product transport device 210 in the Y-axis direction and the Z-axis direction, based on coordinate values in 2-axis directions of the position-display hole 351, that is, coordinate values in the Y-axis direction and the Z-axis direction, with respect to a cross point of the cross axis 341 of an image captured by the sensing portion 340, which is an IPS sensor.

Also, the transport position aligning operation S300 may include: a process S310 of moving the first product transport device 110 in the Y-axis direction or the Z-axis direction; and aligning the position of the first product transport device 110 by moving the first product transport device 110 in the Y-axis direction or the Z-axis direction so that the cross point of the cross axis 341 is positioned at the center of the position-display hole 351.

Also, the position sensing operation S200 may further include a transport direction sensing process S230 of sensing an angle of the first product transport device 110 with respect to a transport direction thereof in a plan view.

The transport direction sensing process S230 may include sensing an angle of the first product transport device 110 with respect to a transport direction thereof in a plan view. In an embodiment, for example, the angle of the first product transport device 110 in the plan view may be sensed by measuring distances between the first product transport device 110 and the second product transport device 210 by using the first distance sensing portion 321 and the second distance sensing portion 322 that are positioned at both sides of the first product transport device 110 to be apart from each other.

When the distances measured by the first distance sensing portion 321 and the second distance sensing portion 322 are different from each other, the transport direction sensing process S230 may include identifying that the first product transport device 110 may not be linearly aligned with the second product transport device 210 and may be positioned to deviate from the second product transport device 210.

When the distances measured by the first distance sensing portion 321 and the second distance sensing portion 322 are the same as each other, the transport direction sensing process S230 may include identifying that the first product transport device 110 may be linearly aligned with the second product transport device 210.

Also, the transport position aligning operation S300 may include a transport direction changing process S320 of changing an angle of the first product transport device 110 with respect to a transport direction thereof in a plan view, and the transport direction changing process S320 may, for example, include changing the angle of the first product transport device 110 with respect to the transport direction thereof in the plan view by selectively operating the plurality of 2-axis movement units 431 capable of moving, in the X-axis direction and the Y-axis direction, the base support portion 420, on an upper surface of which the first product transport device 110 is positioned.

When the product 10 having a certain length or greater is linearly moved and transported by the first product transport device 110 and the second product transport device 210, the first product transport device 110 and the second product transport device 210 may have to be linearly maintained, until a time point at which the transport of the product 10 is completed, that is, until the product 10 is positioned only at the second product transport device 210.

Thus, until the time point at which the transport of the product 10 is completed through the transport direction sensing process S230 and the transport direction changing process S320, the first product transport device 110 and the second product transport device 210 may be linearly aligned with each other so that the product 10 having a certain length or greater may be stably transmitted through the first product transport device 110 and the second product transport device 210.

The 2-axis movement unit 431 may be a well-known unit capable of moving the base support portion 420 in the X-axis direction, which is a transport direction of the product 10, and the Y-axis direction, which is a direction perpendicular thereto, and thus, more detailed descriptions thereof will be omitted.

The alignment method for non-contact transport according to an embodiment may further include, before the position sensing operation S200, a transport device moving operation S100 of moving the first product transport device 110 and positioning the first product transport device 110 at a transport position that is apart from the second product transport device 210.

In an embodiment, for example, the transport device moving operation S100 may include moving the first product transport device 110 to face the second product transport device 210 by using a well-known driving device structure including driving wheels rolling on the ground surface.

Also, the transport position aligning operation S300 may further include a distance re-adjusting process S330 of re-adjusting the distance between the first product transport device 110 and the second product transport device 210 by forwardly and backwardly moving the first product transport device 110 in the X-axis direction, that is, the same direction as the transport direction of the product 10, the first product transport device being positioned at the transport position that is apart from the second product transport device 210.

Through the distance re-adjusting process S330, the distance between the first product transport device 110 and the second product transport device 210 may be finely re-adjusted, and thus, malfunction during the transport may be effectively prevented, and the product 10 may be precisely and reliably transported from the first product transport device 110 to the second product transport device 210.

That is, in the alignment method for non-contact transport according to an embodiment, while the first product transport device 110 is being moved adjacent to the second product transport device 210, positions of the second product transport device 210 with respect to the Y-axis direction and the Z-axis direction may be sensed through the first position sensing process S210 and the second position sensing process S220, and then, the first product transport device 110 may be moved in the Y-axis direction or the Z axis direction to have an aligned position. In such an embodiment, an angle of the first product transport device 110 with respect to a transport direction thereof in a plan view may be sensed through the transport direction sensing process S230, and then, the angle of the first product transport device 110 with respect to the transport direction thereof in the plan view may be changed through the transport direction changing process S320. Accordingly, the first product transport device 110 and the second product transport device 210 may be linearly aligned and may not deviate from each other not only in the X-axis, Y-axis, and Z-axis directions, but also in the plan view.

Also, in the alignment method for non-contact transport according to an embodiment, after the first product transport device 110 and the second product transport device 210 are linearly aligned, the distance between the first product transport device 110 and the second product transport device 210 may be finely re-adjusted, and thus, malfunction during the transport may be prevented, and the product 10 may be precisely and reliably transported from the first product transport device 110 to the second product transport device 210.

According to embodiments of the alignment device for non-contact transport and the alignment method for non-contact transport, the transport positions of the first product transport portion 100 and the second product transport portion 200, which are configured to linearly move and transport the product 10 in a non-contact way, may be rapidly and precisely aligned. Thus, when the product 10 in a standing state is transported by using a non-contact transport device such as a magnetic levitation movement device, the transport efficiency and the transport stability may be greatly improved.

In particular, according to embodiments of the alignment device for non-contact transport and the alignment method for non-contact transport, when, after any one product transport portion of the two product transport portions is moved adjacent to the other product transport portion, the product 10 is linearly moved and transported in a non-contact way, the transport positions may be rapidly and precisely aligned, and thus, the transport efficiency and the transport stability may be greatly improved during the transport of the product 10.

The disclosure is not limited to the embodiment described above. The disclosure may be implemented by making various changes thereto within a range not deviating from the gist of the disclosure, and it shall be noted that these changes are included in the configuration of the disclosure.

According to embodiments, transport positions of a first product transport portion and a second product transport portion, which are configured to linearly move and transport a product in a non-contact way, may be rapidly and precisely aligned. Thus, when a product in a standing state is transported by using a non-contact transport device such as a magnetic levitation movement device, the transport efficiency and the transport stability may be greatly improved.

In particular, according to embodiments, when, after any one product transport portion of the two product transport portions is moved adjacent to the other product transport portion, the product is linearly moved and transported in a non-contact way, the transport positions may be rapidly and precisely aligned, and thus, the transport efficiency and the transport stability may be greatly improved during the transport of the product.

These general and specific embodiments may be implemented by using a system, a method, a computer program, or a combination of the system, the method, and the computer program.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An alignment device for non-contact transport comprising:
a transport alignment movement portion which adjusts an exit position of a first product transport device, wherein the first product transport device linearly moves a product, which is a transport object and mounted therein;
a transport position sensing portion which senses an entrance position of a second product transport device positioned to be apart from the first product transport device, wherein the second product transport device linearly moves the product by receiving the product linearly moved by the first product transport device; and
an alignment control portion which adjusts, by controlling an operation of the transport alignment movement portion, the exit position of the first product transport device based on the entrance position of the second product transport device sensed by the transport position sensing portion.

2. The alignment device for non-contact transport of claim 1, wherein the transport position sensing portion comprises a first entrance position sensing portion which senses the entrance position of the second product transport device in a second direction, wherein a transport direction of the product transported by the first product transport device is a first direction perpendicular to the second direction in a plan view, and
the transport alignment movement portion comprises an alignment movement device which adjusts the exit position of the first product transport device by moving the first product transport device in a direction different from the first direction in the plan view.

3. The alignment device for non-contact transport of claim 2, wherein the transport position sensing portion further comprises a linear movement direction sensing portion which senses an angle of the first product transport device with respect to a transport direction of the first product transport device in the plan view, and
the transport alignment movement portion further comprises:
a base support portion, on which the first product transport device is positioned; and
an angle-adjusting planar movement portion positioned below the base support portion, wherein the angle-adjusting planar movement portion adjusts the angle of the first product transport device with respect to the transport direction of the first product transport device by adjusting an angle of the base support portion in the plan view.

4. The alignment device for non-contact transport of claim 3, wherein the linear movement direction sensing portion comprises a first distance sensing portion and a second distance sensing portion which are positioned at opposing sides of the first product transport device, respectively, to be apart from each other, wherein the first distance sensing portion and the second distance sensing portion sense a distance between the first product transport device and the second product transport device.

5. The alignment device for non-contact transport of claim 3, wherein the angle-adjusting planar movement portion comprises a plurality of 2-axis movement units movable in the first direction and the second direction.

6. The alignment device for non-contact transport of claim 2, wherein the transport position sensing portion further comprises a second entrance position sensing portion which senses a height of the first product transport device, and
the transport alignment movement portion further comprises a transport ascend and descend device which ascends and descends the first product transport device.

7. The alignment device for non-contact transport of claim 6, wherein the first entrance position sensing portion and the second entrance position sensing portion comprise:
a sensing portion based on a camera, which is mounted at one of a first transport portion including the first product transport device and a second transport portion including the second product transport device; and
a reference position display portion mounted at the other of the first transport portion and the second transport portion, wherein the reference position display portion displays a reference position identified through an image captured by the sensing portion.

8. The alignment device for non-contact transport of claim 1, further comprising a transport driving portion which moves the first product transport device toward the second product transport device and sets a distance between the first product transport device and the second product transport device,
wherein the transport alignment movement portion comprises a distance-adjusting device which re-adjusts the distance between the first product transport device and the second product transport device, which is set by the transport driving portion, by forwardly or backwardly moving the first product transport device in a direction identical to a transport direction of the product.

9. An alignment method for non-contact transport for aligning an exit of a first product transport device with an entrance of a second product transport device when linearly moving a product from the first product transport device to the second product transport device, which are positioned to be apart from each other, wherein each of the first product transport device and the second product transport device linearly moves the product, the alignment method for non-contact transport comprising:
performing a position sensing operation by identifying a position of the second product transport device; and
performing a transport position aligning operation by linearly aligning the first product transport device with the second product transport device, by adjusting a position of the first product transport device after the performing the position sensing operation.

10. The alignment method for non-contact transport of claim 9, wherein the performing the position sensing operation comprises:
performing a first position sensing process by sensing a position of the second product transport device with respect to a second direction, wherein a linear movement direction of the product is a first direction different from the second direction; and
performing a second position sensing process by sensing a position of the second product transport device with respect to a third direction different from the first direction, and
the performing the transport position aligning operation comprises performing a process of moving the first product transport device in the second direction or the third direction.

11. The alignment method for non-contact transport of claim 10, wherein the performing the first position sensing process and the performing the second position sensing process comprise sensing the positions of the second product transport device with respect to the second direction and the third direction by identifying a position-display hole of a target bracket positioned at the second product transport device through a sensing portion based on a camera, which is positioned at the first product transport device.

12. The alignment method for non-contact transport of claim 10, wherein the performing the position sensing operation further comprises performing a transport direction sensing process by sensing an angle of the first product transport device with respect to a transport direction of the first product transport device in a plan view, and
the performing the transport position aligning operation further comprises performing a transport direction changing process by changing the angle of the first product transport device with respect to the transport direction of the first product transport device in the plan view,
wherein the performing the transport direction changing process comprises changing the angle of the first product transport device with respect to the transport direction of the first product transport device in the plan view by selectively operating a plurality of 2-axis movement units which moves a base support portion with the first product transport device positioned thereon in the first direction and second direction.

13. The alignment method for non-contact transport of claim 12, wherein the performing the transport direction sensing process comprises sensing the angle of the first product transport device in the plan view by measuring a distance between the first product transport device and the second product transport device through a first distance sensing portion and a second distance sensing portion which are positioned at opposing sides of the first product transport device to be apart from each other.

14. The alignment method for non-contact transport of claim 9, further comprising, before the performing the position sensing operation, performing a transport device movement operation by moving the first product transport device via a transport driving portion and positioning the first product transport device at a transport position that is apart from the second product transport device,
wherein the performing the transport position aligning operation further comprises performing a distance re-adjusting process by re-adjusting a distance between the first product transport device and the second product transport device by forwardly or backwardly moving, in a direction which is identical to a transport direction of the product, wherein the first product transport device is positioned at the transport position apart from the second product transport device.
